(19) United States
(12) Patent Application Publication
(10) Pub. No.: US 2021/0327337 A1
(43) Pub. Date: Oct. 21, 2021

(54) GATE DRIVING CIRCUIT, CONTROLLING METHOD THEREOF, AND DISPLAY DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Zhenfei CAI, Shenzhen (CN)

(73) Assignee: Shenzhen China Star Optoelectronics Semiconductor Display Technology Co., Ltd., Shenzhen, Guangdong (CN)

(21) Appl. No.: 16/627,808

(22) PCT Filed: Dec. 17, 2019
(86) PCT No.: PCT/CN2019/126067

§ 371 Date: Dec. 31, 2019

(30) Foreign Application Priority Data
Dec. 2, 2019 (CN) 201911216131.2

(51) Int. Cl. G09G 3/20

(52) U.S. Cl. CPC G09G 3/2092; G09G 2310/08

(57) ABSTRACT

The present disclosure provides a gate driving circuit, a controlling method thereof, and a display device. The gate driving circuit includes a primary pull-up driving unit, a primary pull-up unit, a primary pull-down driving unit, a primary pull-down unit, a secondary pull-up driving unit, a secondary pull-up unit, and a secondary pull-down unit. In the present disclosure, when outputting in one stage, a clock signal of the other stage is at low electrical potential and turns off the pull-down transistor, to implement the interlock circuit when outputting, and at the same time to implement a two-stage output signal triggered by a trigger signal STU.

### FIELD OF INVENTION

The present disclosure relates to the field of display technologies, and more particularly to a gate driving circuit, a method for controlling the gate driving circuit, and a display device.

### BACKGROUND OF INVENTION

A gate on array (GOA) circuit used in the prior art is shown in FIG. 1, wherein Cout (n−1) is a previous-stage of a Cout signal, CLK and CLKB are two complementary clock signals, and Cout (n+1) is a next-stage of the Cout signal, this circuit can realize a conventional shift register function, and one GOA unit implements one gate signal line output.

However, with the development of technology, it is necessary to compress the GOA unit when realizing technologies such as large-size narrow frames of a display device.

### SUMMARY OF INVENTION

The present disclosure provides a gate driving circuit, a method for controlling the gate driving circuit, and a display device, solving the problems that the prior art technology can not realize large-size narrow frames of a display device.

In one aspect, the present disclosure provides a gate driving circuit comprising a primary pull-up driving unit, a primary pull-up unit, a primary pull-down driving unit, a primary pull-down unit, a secondary pull-up driving unit, a secondary pull-up unit, and a secondary pull-down unit;

wherein the primary pull-up driving unit is respectively connected to the primary pull-up unit, the primary pull-down driving unit, and the primary pull-down unit, the primary pull-up unit is further respectively connected to the primary pull-down unit and the secondary pull-up driving unit, the primary pull-down driving unit is further connected to the primary pull-down unit, the secondary pull-up driving unit is further respectively connected to the secondary pull-up unit and the secondary pull-down unit, and the secondary pull-up unit is further connected to the secondary pull-down unit;

wherein the primary pull-up driving unit respectively receives a first clock signal, a second clock signal, and a trigger signal, the primary pull-down driving unit receives a control signal, the secondary pull-up driving unit receives the first clock signal and a third clock signal, the secondary pull-down unit receives the first clock signal, a Q point is respectively connected to the primary pull-up driving unit and the primary pull-down driving unit, a QB point is respectively connected to the primary pull-up driving unit, the primary pull-down driving unit, and the primary pull-down unit, a primary output terminal is respectively connected to the primary pull-up unit and the primary pull-down driving unit, a secondary output terminal is respectively connected to the secondary pull-up unit and the secondary pull-down unit.

In the gate driving circuit of the present disclosure, the primary pull-up driving unit comprises a first transistor, a second transistor, a third transistor, a fourth transistor, a fifth transistor, a sixth transistor, and a first capacitor;

a gate of the first transistor receives the first clock signal, a drain and a source of the first transistor are respectively connected to the trigger signal and a first node, a gate of the second transistor receives the first clock signal, a drain and a source of the second transistor are respectively connected to the first node and the Q point, a gate of the third transistor is connected to the Q point, a drain and a source of the third transistor are respectively connected to the first node and a high electrical potential terminal, a gate of the fourth transistor is connected to the Q point, a source and a drain of the fourth transistor are respectively connected to a second node and the second clock signal, a gate of the fifth transistor is connected to the QB point, a drain and a source of the fifth transistor are respectively connected to the first node and the Q point, a gate of the sixth transistor is connected to the QB point, a source and a drain of the sixth transistor are respectively connected to the first node and a low electrical potential terminal, and two terminals of the first capacitor are respectively connected to the Q point and the second node.

In the gate driving circuit of the present disclosure, the primary pull-up unit comprises a seventh transistor and a second capacitor;

a gate of the seventh transistor is connected to the second node, a drain and a source of the seventh transistor are respectively connected to a driving electrical potential terminal and the primary output terminal, and two terminals of the second capacitor are respectively connected to the second node and the primary output terminal.

In the gate driving circuit of the present disclosure, the primary pull-down driving unit comprises an eighth transistor and a ninth transistor;

a gate of the eighth transistor receives the control signal, a source and a drain of the eighth transistor are respectively connected to the high electrical potential terminal and the QB point, and a gate of the ninth transistor is connected to the Q point, a source and a drain of the ninth transistor are respectively connected to the QB point and the low electrical potential terminal.

In the gate driving circuit of the present disclosure, the primary pull-down unit comprises a tenth transistor and an eleventh transistor;

a gate of the tenth transistor is connected to the QB point, a source and a drain of the tenth transistor are respectively connected to the second node and the low electrical potential terminal, a gate of the eleventh transistor is connected to the QB point, a source and a drain of the eleventh transistor are respectively connected to the primary output terminal and the low electrical potential terminal.

In the gate driving circuit of the present disclosure, the secondary pull-up driving unit comprises a twelfth transistor, a thirteenth transistor, and a fourteenth transistor;

a gate of the twelfth transistor is connected to the second node, a source and a drain of the twelfth transistor are respectively connected to the primary output terminal and a third node, a gate of the thirteenth transistor receives a third clock signal, a source and a drain of the thirteenth transistor are respectively connected to the third node and a fourth node, and a gate of the fourteenth transistor receives the first clock signal, a source and a drain of the fourteenth transistor are respectively connected to the third node and the low electrical potential terminal.

In the gate driving circuit of the present disclosure, the secondary pull-up unit comprises a fifteenth transistor and a third capacitor;

a gate of the fifteenth transistor is connected to the fourth node, a source and a drain of the fifteenth transistor are respectively connected to the driving electrical potential terminal and the secondary output terminal, and two terminals of the third capacitor are respectively connected to the fourth node and the secondary output terminal.

In the gate driving circuit of the present disclosure, the secondary pull-down unit comprises a sixteenth transistor;

a gate of the sixteenth transistor receives the first clock signal, and a source and a drain of the sixteenth transistor are respectively connected to the secondary output terminal and the low electrical potential terminal.

In one aspect, the present disclosure provides a method for controlling a gate driving circuit, which is implemented by using a gate driving circuit, wherein the gate driving circuit comprises a primary pull-up driving unit, a primary pull-up unit, a primary pull-down driving unit, a primary pull-down unit, a secondary pull-up driving unit, a secondary pull-up unit, and a secondary pull-down unit;

wherein the primary pull-up driving unit is respectively connected to the primary pull-up unit, the primary pull-down driving unit, and the primary pull-down unit, the primary pull-up unit is further respectively connected to the primary pull-down unit and the secondary pull-up driving unit, the primary pull-down driving unit is further connected to the primary pull-down unit, the secondary pull-up driving unit is further respectively connected to the secondary pull-up unit and the secondary pull-down unit, and the secondary pull-up unit is further connected to the secondary pull-down unit;

wherein the primary pull-up driving unit respectively receives a first clock signal, a second clock signal, and a trigger signal, the primary pull-down driving unit receives a control signal, the secondary pull-up driving unit receives the first clock signal and a third clock signal, the secondary pull-down unit receives the first clock signal, a Q point is respectively connected to the primary pull-up driving unit and the primary pull-down driving unit, a QB point is respectively connected to the primary pull-up driving unit, the primary pull-down driving unit, and the primary pull-down unit, a primary output terminal is respectively connected to the primary pull-up unit and the primary pull-down driving unit, a secondary output terminal is respectively connected to the secondary pull-up unit and the secondary pull-down unit, wherein the control method comprises:

setting the first clock signal and the trigger signal to a high electrical potential, and setting the second clock signal, the third clock signal, and the control signal to a low electrical potential to increase a voltage of the Q point and reduce a voltage of the QB point;

setting the second clock signal to the high electrical potential, and setting the first clock signal, the trigger signal, and the control signal to the low electrical potential, so as to according a voltage of the Q point to output a voltage of a driving electrical potential terminal to the primary output terminal;

setting the first clock signal, the second clock signal, and the trigger signal to the low electrical potential, and setting the control signal and the third clock signal to the high electrical potential, to pull up a voltage of the QB point and output a voltage of the driving electrical potential terminal to the secondary output terminal; and setting the first clock signal to the high electrical potential, and setting the second clock signal, the third clock signal, the trigger signal, and the control signal to the low electrical potential to pull down a voltage of the secondary output terminal.

In one aspect, the present disclosure provides a display device, which including the gate driving circuit described above.

The beneficial effect of the present disclosure: when the secondary output terminal outputs, the first clock signal at low electrical potential turns off the secondary pull-down unit, and when the primary output terminal outputs, the control signal at low electrical potential to turn off the primary pull-down unit. This implements the interlock circuit when outputting, and at the same time, implements a two-stage output signal triggered by a trigger signal STU.

### DESCRIPTION OF FIGURES

The present disclosure will be further described below with reference to the accompanying figures and embodiments. In the figures:

FIG. 1 is a structural diagram of a gate driving circuit in the prior art.

FIG. 2 is a structural diagram of a gate driving circuit according to an embodiment of the present disclosure.

FIG. 3 is a time sequence diagram of the gate driving circuit according to an embodiment of the present disclosure.

FIG. 4 is a flowchart of a controlling method of the gate driving circuit according to an embodiment of the present disclosure.

FIG. 5 is a realistic time sequence diagram of the gate driving circuit according to an embodiment of the present disclosure.

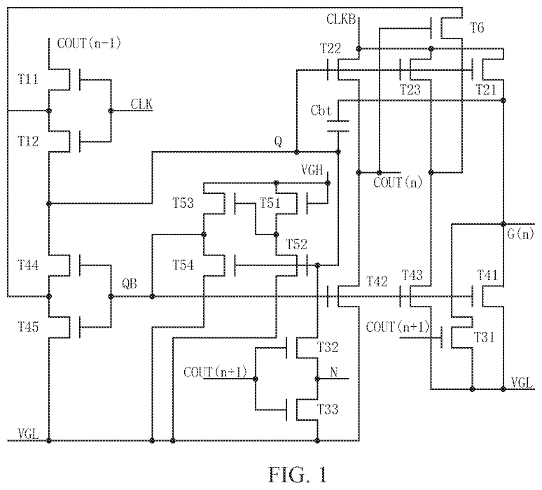

### DETAILED DESCRIPTION OF PREFERRED EMBODIMENTS

To have a clearer understanding of the technical features, objects, and effects of the present disclosure, specific embodiments of the present disclosure be described in detail with reference to the figures.

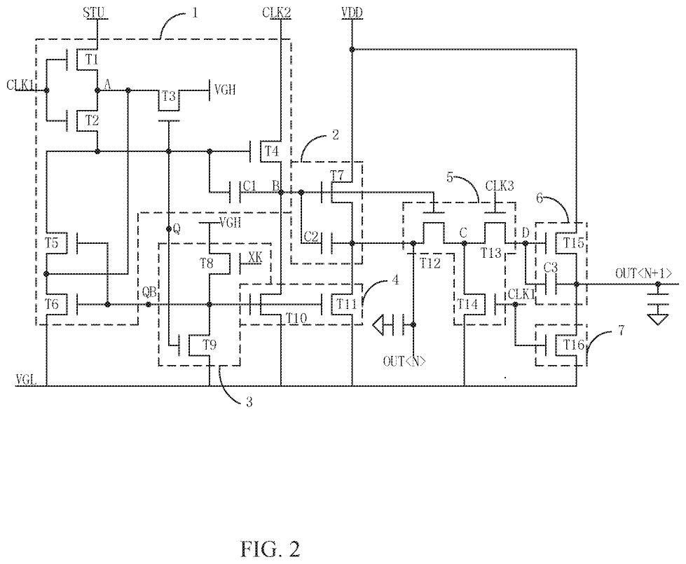

Please refer to FIG. 2, FIG. 2 is a structural diagram of a gate driving circuit according to an embodiment of the present disclosure. The gate driving circuit includes a primary pull-up driving unit 1, a primary pull-up unit 2, a primary pull-down driving unit 3, a primary pull-down unit 4, a secondary pull-up driving unit 5, a secondary pull-up unit 6, and a secondary pull-down unit 7; wherein the primary pull-up driving unit 1 is respectively connected to the primary pull-up unit 2, the primary pull-down driving unit 3, and the primary pull-down unit 4. The primary pull-up unit 2 is further respectively connected to the primary pull-down unit 4 and the secondary pull-up driving unit 5, the primary pull-down unit 3 is further connected to the primary pull-down unit 4, the secondary pull-up driving unit 5 is further respectively connected to the secondary pull-up unit 6 and the secondary pull-down unit 7, and the secondary pull-up unit 6 is further connected to the secondary pull-down unit 7; wherein the primary pull-up driving unit 1 respectively receives a first clock signal CLK1, a second clock signal CLK2, and a trigger signal STU, the primary pull-down driving unit 3 receives a control signal XK, the secondary pull-up driving unit 5 receives the first clock signal CLK1 and the third clock signal CLK3, and the secondary pull-down unit 7 receives the first clock signal CLK1, A Q point is respectively connected to the primary pull-up driving unit 1 and the primary pull-down driving unit 3, a QB point is respectively connected to the primary pull-up driving unit 1, the primary pull-down driving unit 3, and the primary pull-down unit 4. A primary output terminal OUT<N> is respectively connected to the primary pull-up unit 2 and the primary pull-down driving unit 3, and a secondary output terminal OUT<N+1> is respectively connected to the secondary pull-up unit 6 and the secondary pull-down unit 7.

The primary pull-up driving unit 1 includes a first transistor T1, a second transistor T2, a third transistor T3, a fourth transistor T4, a fifth transistor T5, a sixth transistor T6, and a first capacitor C1. A gate of the first transistor T1 receives the first clock signal CLK1, and a drain and a source of the first transistor T1 are respectively connected to the trigger signal STU and the first node A. A gate of the second transistor T2 receives the first clock signal CLK1, and a drain and a source of the second transistor T2 are respectively connected to the first node A and the Q point. A gate of the third transistor T3 is connected to the Q point, and a drain and a source of the third transistor T3 are respectively connected to the first node A and a high electrical potential terminal VGH. A gate of the fourth transistor T4 is connected to the Q point, and a source and a drain of the fourth transistor T4 are respectively connected to a second node B and the second clock signal CLK2. A gate of the fifth transistor T5 is connected to the QB point, and a drain and a source of the fifth transistor T5 are respectively connected to the first node A and the Q point. A gate of the sixth transistor is connected to the QB point, and a source and a drain of the sixth transistor T6 are respectively connected to the first node A and a low electrical potential terminal VGL. Two terminals of the first capacitor C1 are respectively connected to the Q Point and the second node B.

The primary pull-up unit 2 includes a seventh transistor T7 and a second capacitor C2; a gate of the seventh transistor T7 is connected to the second node B, a drain and a source of the seventh transistor T7 are respectively connected to a driving electrical potential terminal VDD and the primary output terminal OUT <N>, and two terminals of the second capacitor C2 are respectively connected to the second node B and the primary output terminal OUT<N>.

The primary pull-down driving unit 3 includes an eighth transistor T8 and a ninth transistor T9. A gate of the eighth transistor T8 receives the control signal XK, a source and a drain of the eighth transistor T8 are respectively connected to the high electrical potential terminal VGH and the QB point, a gate of the ninth transistor T9 is connected to the Q point, and a source and a drain of the ninth transistor T9 are respectively connected to the QB point and the low electrical potential terminal VGL.

The primary pull-down unit 4 includes a tenth transistor T10 and an eleventh transistor T11; a gate of the tenth transistor T10 is connected to the QB point, a source and a drain of the tenth transistor T10 are respectively connected to the second node B and the low electrical potential terminal VGL, a gate of the eleventh transistor T11 is connected to the QB point, and a source and a drain of the eleventh transistor T11 are respectively connected to the primary output terminal OUT<N> and low electrical potential terminal VGL.

The secondary pull-up driving unit 5 includes a twelfth transistor T12, a thirteenth transistor T13, and a fourteenth transistor T14. A gate of the twelfth transistor T12 is connected to the second node B, a source and a drain of the twelfth transistor T12 are respectively connected to the primary output terminal OUT<N> and a third node C, a gate of the thirteenth transistor T13 receives a third clock signal CLK3, a source and a drain of the thirteenth transistor T13 are respectively connected to the third node C and a fourth node D, a gate of the fourteenth transistor T14 receives the first clock signal CLK1, and a source and a drain of the fourteenth transistor T14 are respectively connected to the third node C and the low electrical potential terminal VGL.

The secondary pull-up unit 6 includes a fifteenth transistor T15 and a third capacitor C3; a gate of the fifteenth transistor T15 is connected to the fourth node D, a source and a drain of the fifteenth transistor 15 are respectively connected to the driving electrical potential terminal VDD and the secondary output terminal OUT<N+1>, and two terminals of the third capacitor C3 are respectively connected to the fourth node D and the secondary output terminal OUT<N+1>.

The secondary pull-down unit 7 includes a sixteenth transistor T16; a gate of the sixteenth transistor T16 receives the first clock signal CLK1, and a source and a drain of the sixteenth transistor T16 are respectively connected to the secondary output terminal OUT<N+1> and the low electrical potential terminal VGL.

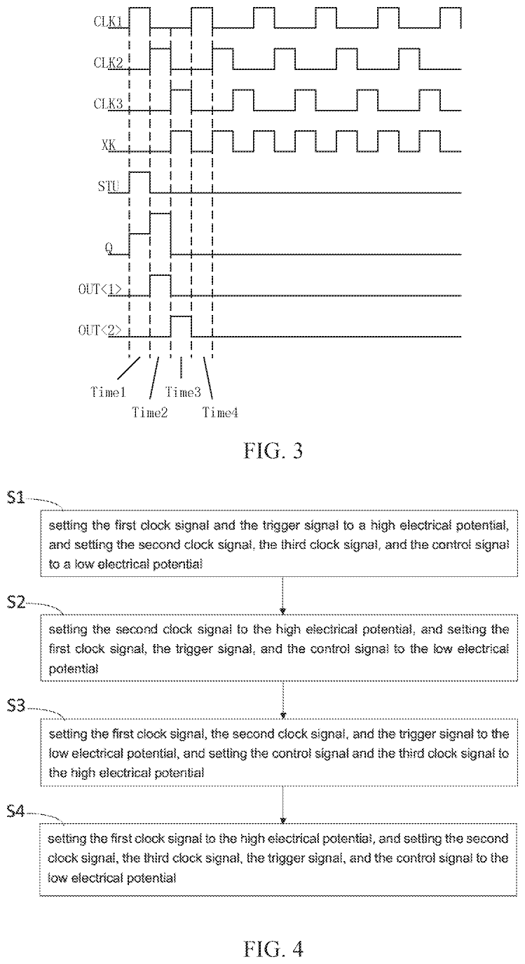

FIG. 3 is a time sequence diagram of the gate driving circuit according to an embodiment of the present disclosure. FIG. 4 is a flowchart of a controlling method of the gate driving circuit according to an embodiment of the present disclosure. Please refer to FIG. 3 and FIG. 4 at the same time. In one aspect, the present disclosure provides a control method of a gate driving circuit, which is implemented by using the gate driving circuit described above, wherein the control method includes steps S1-S4:

S1: Setting the first clock signal CLK1 and the trigger signal STU to a high electrical potential, and setting the second clock signal CLK2, the third clock signal CLK3, and the control signal XK to a low electrical potential to increase a voltage of the Q point and reduce a voltage of the QB point. Please refer to FIG. 3 for the time sequence diagram of the controlling method, which corresponds to the Time1 step of FIG. 3: the first clock signal CLK1 and the trigger signal STU are at high electrical potential (an initial step OUT (N−1) is replaced by the trigger signal STU), and the second clock signal CLK2, the third clock signal CLK3, and the control signal XK are at low electrical potential, turning on the first transistor T1 and the second transistor T2. The trigger signal STU is transmitted by the first transistor T1 and the second transistor T2 to increase a voltage of the Q point. At the same time, turning on the fourth transistor T4 and the ninth transistor T9, and setting the voltage of the QB point at low level.

S2: Setting the second clock signal CLK2 to the high electrical potential, and setting the first clock signal CLK1, the trigger signal STU, and the control signal XK to the low electrical potential, to output a voltage of the driving electrical potential terminal VDD to the primary output terminal OUT <N> according to a voltage of the Q point. This step corresponds to Time2 step of FIG. 3: the first clock signal CLK1, the trigger signal STU, and the control signal XK are at the low electrical potential, and the second clock signal CLK2 is at the high electrical potential. Since during the Time1 step, pulling up the Q point enough to turn on the fourth transistor T4, therefore transmitting the second clock signal CLK2 into the second node B through the fourth transistor T4. After the coupling effect of the first capacitor C1, pulling up the potential of the Q point again, so that outputting the second clock signal CLK2 to the second node B with almost full swing, that is, the second node B outputs the high electrical potential. The second node B is used as a gate switch of the seventh transistor T7, and turning on the seventh transistor T7, so that outputting the full swing voltage of the driving electrical potential terminal VDD to the primary output terminal OUT <N>. In addition, in the above step, turning on the twelfth transistor T12 at the same time to transmit the voltage across the twelfth transistor T12.

S3: Setting the first clock signal CLK1, the second clock signal CLK2, and the trigger signal STU to a low electrical potential, and setting the control signal XK and the third clock signal CLK3 to the high electrical potential, to pull up a voltage of the QB point and output a voltage of the driving electrical potential terminal VDD to the secondary output terminal OUT<N+1>; this step corresponds to Time3 step of FIG. 3: the first clock signal CLK1, the second clock signal CLK2, and the trigger signal STU are at the low electrical potential, the control signal XK and the third clock signal CLK3 are at the high electrical potential. At the Time3 step, turning on the thirteenth transistor T13, pulling up a gate voltage of the fifteenth transistor T15, and turning on the fifteenth transistor T15, so that outputting the full swing range of the driving electrical potential terminal VDD to the secondary output terminal OUT<N+1>. At this step, the control signal XK is at high electrical potential, turning on the eighth transistor T8, and pulling up a voltage of the QB point, thereby turning on the tenth transistor T10 and the eleventh transistor T11, and pulling down the voltage of the point B and the primary output terminal OUT<N>.

S4: Setting the first clock signal CLK1 to the high electrical potential, and setting the second clock signal CLK2, the third clock signal CLK3, the trigger signal STU, and the control signal XK to the low electrical potential to pull down the voltage of secondary output terminal OUT<N+1>. This step corresponds to Time4 of FIG. 3, the trigger signal STU, the primary output terminal OUT<N>, the second clock signal CLK2, the third clock signal CLK3, and the control signal XK are all at low voltage. At the same time, the first clock signal CLK1 is at a high voltage, turning on the sixteenth transistor T16 and the fourteenth transistor T14, and pulling down the voltage of the secondary output terminal OUT<N+1> and point C.

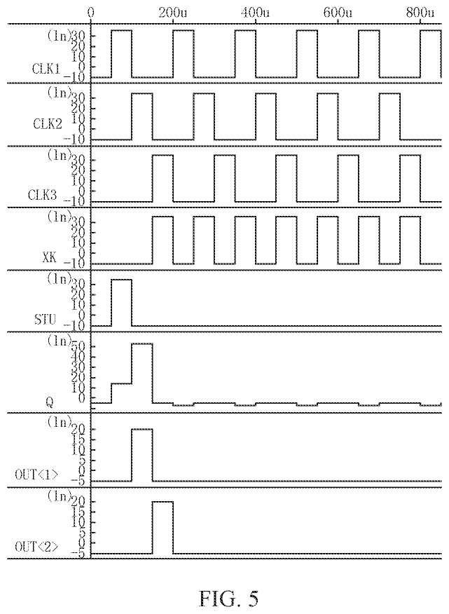

FIG. 5 is a realistic time sequence diagram of the gate driving circuit according to an embodiment of the present disclosure. The simulation voltage values are set as follows: the first clock signal CLK1, the second clock signal CLK2, the third clock signal CLK3, and the control signal XK have a high electrical potential of 30V and a low electrical potential of −10V. The high electrical potential terminal VGH is 25V, the low electrical potential terminal VGL is −5V, the driving electrical potential terminal VDD is 25V, the high electrical potential of the trigger signal STU is 25V, and the low electrical potential is −10V. It can be seen from the realistic time sequence diagram that the primary output terminal OUT <N> and the secondary output terminal OUT<N+1> generates almost no noise at low electrical potential, and almost no distortion at high electrical potential, which proves the accuracy and low power consumption of the gate driving circuit of the present disclosure.

The present disclosure further provides a display device including the gate driving circuit. The gate driving circuit uses one input to realize two-stage output, and when outputting in one stage, the first clock signal CLK1 of the other stage at low electrical potential turns off the sixteenth transistor T16 and the fourteenth transistor T14, and when the primary stage output terminal OUT<N> outputs, the control signal XK turns off the tenth transistor T10 and the eleventh transistor T11 to implement the interlock circuit when outputting.

The embodiments of the present disclosure have been described above with reference to the accompanying figures, but the present disclosure is not limited to the above specific implementations, and the above specific implementations are merely for schematic, not restrictive. People skilled in the art may, under the inspiration of the present disclosure, make many forms without departing from the spirit of the present disclosure and the scope of protection of the claims, which all fall within the protection of the present disclosure.

What is claimed is:

1. A gate driving circuit comprising a primary pull-up driving unit, a primary pull-up unit, a primary pull-down driving unit, a primary pull-down unit, a secondary pull-up driving unit, a secondary pull-up unit, and a secondary pull-down unit;
wherein the primary pull-up driving unit is respectively connected to the primary pull-up unit, the primary pull-down driving unit, and the primary pull-down unit, the primary pull-up unit is further respectively connected to the primary pull-down unit and the secondary pull-up driving unit, the primary pull-down driving unit is further connected to the primary pull-down unit, the secondary pull-up driving unit is further respectively connected to the secondary pull-up unit and the secondary pull-down unit, and the secondary pull-up unit is further connected to the secondary pull-down unit;
wherein the primary pull-up driving unit respectively receives a first clock signal, a second clock signal, and a trigger signal, the primary pull-down driving unit receives a control signal, the secondary pull-up driving unit receives the first clock signal and a third clock signal, the secondary pull-down unit receives the first clock signal, a Q point is respectively connected to the primary pull-up driving unit and the primary pull-down driving unit, a QB point is respectively connected to the primary pull-up driving unit, the primary pull-down driving unit, and the primary pull-down unit, a primary output terminal is respectively connected to the primary pull-up unit and the primary pull-down driving unit, and a secondary output terminal is respectively connected to the secondary pull-up unit and the secondary pull-down unit.

2. The gate driving circuit as claimed in claim 1, wherein the primary pull-up driving unit comprises a first transistor, a second transistor, a third transistor, a fourth transistor, a fifth transistor, a sixth transistor, and a first capacitor;
a gate of the first transistor receives the first clock signal, a drain and a source of the first transistor are respectively connected to the trigger signal and a first node, a gate of the second transistor receives the first clock signal, a drain and a source of the second transistor are respectively connected to the first node and the Q point, a gate of the third transistor is connected to the Q point, a drain and a source of the third transistor are respectively connected to the first node and a high electrical potential terminal, a gate of the fourth transistor is connected to the Q point, a source and a drain of the fourth transistor are respectively connected to a second node and the second clock signal, a gate of the fifth transistor is connected to the QB point, a drain and a source of the fifth transistor are respectively connected to the first node and the Q point, a gate of the sixth transistor is connected to the QB point, a source and a drain of the sixth transistor are respectively connected to the first node and a low electrical potential terminal, and two terminals of the first capacitor are respectively connected to the Q point and the second node.

3. The gate driving circuit as claimed in claim 2, wherein the primary pull-up unit comprises a seventh transistor and a second capacitor;
a gate of the seventh transistor is connected to the second node, a drain and a source of the seventh transistor are respectively connected to a driving electrical potential terminal and the primary output terminal, and two terminals of the second capacitor are respectively connected to the second node and the primary output terminal.

4. The gate driving circuit as claimed in claim 3, wherein the primary pull-down driving unit comprises an eighth transistor and a ninth transistor;
a gate of the eighth transistor receives the control signal, a source and a drain of the eighth transistor are respectively connected to the high electrical potential terminal and the QB point, a gate of the ninth transistor is connected to the Q point, and a source and a drain of the ninth transistor are respectively connected to the QB point and the low electrical potential terminal.

5. The gate driving circuit as claimed in claim 4, wherein the primary pull-down unit comprises a tenth transistor and an eleventh transistor;
a gate of the tenth transistor is connected to the QB point, a source and a drain of the tenth transistor are respectively connected to the second node and the low electrical potential terminal, a gate of the eleventh transistor is connected to the QB point, and a source and a drain of the eleventh transistor are respectively connected to the primary output terminal and the low electrical potential terminal.

6. The gate driving circuit as claimed in claim 5, wherein the secondary pull-up driving unit comprises a twelfth transistor, a thirteenth transistor, and a fourteenth transistor;
a gate of the twelfth transistor is connected to the second node, a source and a drain of the twelfth transistor are respectively connected to the primary output terminal and a third node, a gate of the thirteenth transistor receives the third clock signal, a source and a drain of the thirteenth transistor are respectively connected to the third node and a fourth node, and a gate of the fourteenth transistor receives the first clock signal, and a source and a drain of the fourteenth transistor are respectively connected to the third node and the low electrical potential terminal.

7. The gate driving circuit as claimed in claim 6, wherein the secondary pull-up unit comprises a fifteenth transistor and a third capacitor;
a gate of the fifteenth transistor is connected to the fourth node, a source and a drain of the fifteenth transistor are respectively connected to the driving electrical potential terminal and the secondary output terminal, and two terminals of the third capacitor are respectively connected to the fourth node and the secondary output terminal.

8. The gate driving circuit as claimed in claim 7, wherein the secondary pull-down unit comprises a sixteenth transistor;
a gate of the sixteenth transistor receives the first clock signal, and a source and a drain of the sixteenth transistor are respectively connected to the secondary output terminal and the low electrical potential terminal.

9. A method for controlling a gate driving circuit, which is implemented by using the gate driving circuit, wherein the gate driving circuit comprises a primary pull-up driving unit, a primary pull-up unit, a primary pull-down driving unit, a primary pull-down unit, a secondary pull-up driving unit, a secondary pull-up unit, and a secondary pull-down unit;
wherein the primary pull-up driving unit is respectively connected to the primary pull-up unit, the primary pull-down driving unit, and the primary pull-down unit, the primary pull-up unit is further respectively connected to the primary pull-down unit and the secondary pull-up driving unit, the primary pull-down driving unit is further connected to the primary pull-down unit, the secondary pull-up driving unit is further respectively connected to the secondary pull-up unit and the secondary pull-down unit, and the secondary pull-up unit is further connected to the secondary pull-down unit;
wherein the primary pull-up driving unit respectively receives a first clock signal, a second clock signal, and a trigger signal, the primary pull-down driving unit receives a control signal, the secondary pull-up driving unit receives the first clock signal and a third clock signal, the secondary pull-down unit receives the first clock signal, a Q point is respectively connected to the primary pull-up driving unit and the primary pull-down driving unit, a QB point is respectively connected to the primary pull-up driving unit, the primary pull-down driving unit, and the primary pull-down unit, a primary output terminal is respectively connected to the primary pull-up unit and the primary pull-down driving unit, and a secondary output terminal is respectively connected to the secondary pull-up unit and the secondary pull-down unit, wherein the control method comprises:
setting the first clock signal and the trigger signal to a high electrical potential, and setting the second clock signal, the third clock signal, and the control signal to a low electrical potential to increase a voltage of the Q point and reduce a voltage of the QB point;
setting the second clock signal to the high electrical potential, and setting the first clock signal, the trigger signal, and the control signal to the low electrical potential, to output a voltage of a driving electrical potential terminal to the primary output terminal according to a voltage of the Q point;
setting the first clock signal, the second clock signal, and the trigger signal to the low electrical potential, and setting the control signal and the third clock signal to the high electrical potential, to pull up a voltage of the QB point and output a voltage of the driving electrical potential terminal to the secondary output terminal; and
setting the first clock signal to the high electrical potential, and setting the second clock signal, the third clock signal, the trigger signal, and the control signal to the low electrical potential to pull down a voltage of the secondary output terminal.

10. The control method as claimed in claim 9, wherein the primary pull-up driving unit comprises a first transistor, a second transistor, a third transistor, a fourth transistor, a fifth transistor, a sixth transistor, and a first capacitor;
a gate of the first transistor receives the first clock signal, a drain and a source of the first transistor are respectively connected to the trigger signal and a first node, a gate of the second transistor receives the first clock signal, a drain and a source of the second transistor are respectively connected to the first node and the Q point, the gate of the third transistor is connected to the Q point, a drain and a source of the third transistor are respectively connected to the first node and a high electrical potential terminal, a gate of the fourth transistor is connected to the Q point, a source and a drain of the fourth transistor are respectively connected to a second node and the second clock signal, a gate of the fifth transistor is connected to the QB point, a drain and a source of the fifth transistor are respectively connected to the first node and the Q point, a gate of the sixth transistor is connected to the QB point, a source and a drain of the sixth transistor are respectively connected to the first node and the low electrical potential terminal, and two terminals of the first capacitor are respectively connected to the Q point and the second node.

11. The control method as claimed in claim 10, wherein the primary pull-up unit comprises a seventh transistor and a second capacitor;
a gate of the seventh transistor is connected to the second node, a drain and a source of the seventh transistor are respectively connected to the driving electrical potential terminal and the primary output terminal, and two terminals of the second capacitor are respectively connected to the second node and the primary output terminal.

12. The control method as claimed in claim 11, wherein the primary pull-down driving unit comprises an eighth transistor and a ninth transistor;
a gate of the eighth transistor receives the control signal, a source and a drain of the eighth transistor are respectively connected to the high electrical potential terminal and the QB point, a gate of the ninth transistor is connected to the Q point, and a source and a drain of the ninth transistor are respectively connected to the QB point and the low electrical potential terminal.

13. The control method as claimed in claim 12, wherein the primary pull-down unit comprises a tenth transistor and an eleventh transistor;
a gate of the tenth transistor is connected to the QB point, a source and a drain of the tenth transistor are respectively connected to the second node and the low electrical potential terminal, a gate of the eleventh transistor is connected to the QB point, and a source and a drain of the eleventh transistor are respectively connected to the primary output terminal and the low electrical potential terminal.

14. The control method as claimed in claim 13, wherein the secondary pull-up driving unit comprises a twelfth transistor, a thirteenth transistor, and a fourteenth transistor;
a gate of the twelfth transistor is connected to the second node, a source and a drain of the twelfth transistor are respectively connected to the primary output terminal and a third node, a gate of the thirteenth transistor receives the third clock signal, a source and a drain of the thirteenth transistor are respectively connected to the third node and a fourth node, and a gate of the fourteenth transistor receives the first clock signal, and a source and a drain of the fourteenth transistor are respectively connected to the third node and the low electrical potential terminal.

15. The control method as claimed in claim 14, wherein the secondary pull-up unit comprises a fifteenth transistor and a third capacitor;
a gate of the fifteenth transistor is connected to the fourth node, a source and a drain of the fifteenth transistor are respectively connected to the driving electrical potential terminal and the secondary output terminal, and two terminals of the third capacitor are respectively connected to the fourth node and the secondary output terminal.

16. The control method as claimed in claim 15, wherein the secondary pull-down unit comprises a sixteenth transistor;
a gate of the sixteenth transistor receives the first clock signal, and a source and a drain of the sixteenth transistor are respectively connected to the secondary output terminal and the low electrical potential terminal.

17. A display device comprising a gate driving circuit, wherein the gate driving circuit comprises a primary pull-up driving unit, a primary pull-up unit, a primary pull-down driving unit, a primary pull-down unit, a secondary pull-up driving unit, a secondary pull-up unit, and a secondary pull-down unit;
wherein the primary pull-up driving unit is respectively connected to the primary pull-up unit, the primary pull-down driving unit, and the primary pull-down unit, the primary pull-up unit is further respectively connected to the primary pull-down unit and the secondary pull-up driving unit, the primary pull-down driving unit is further connected to the primary pull-down unit, the secondary pull-up driving unit is further respectively connected to the secondary pull-up unit and the secondary pull-down unit, and the secondary pull-up unit is further connected to the secondary pull-down unit;
wherein the primary pull-up driving unit respectively receives a first clock signal, a second clock signal, and a trigger signal, the primary pull-down driving unit receives a control signal, the secondary pull-up driving unit receives the first clock signal and a third clock signal, the secondary pull-down unit receives the first clock signal, a Q point is respectively connected to the primary pull-up driving unit and the primary pull-down driving unit, a QB point is respectively connected to the primary pull-up driving unit, the primary pull-down driving unit, and the primary pull-down unit, a primary output terminal is respectively connected to the primary pull-up unit and the primary pull-down driving unit, and a secondary output terminal is respectively connected to the secondary pull-up unit and the secondary pull-down unit.

18. The display device as claimed in claim 17, wherein the primary pull-up driving unit comprises a first transistor, a second transistor, a third transistor, a fourth transistor, a fifth transistor, a sixth transistor, and a first capacitor;
a gate of the first transistor receives the first clock signal, a drain and a source of the first transistor are respectively connected to the trigger signal and a first node, a gate of the second transistor receives the first clock signal, a drain and a source of the second transistor are respectively connected to the first node and the Q point, the gate of the third transistor is connected to the Q point, a drain and a source of the third transistor are respectively connected to the first node and a high electrical potential terminal, a gate of the fourth transistor is connected to the Q point, a source and a drain of the fourth transistor are respectively connected to a second node and the second clock signal, a gate of the fifth transistor is connected to the QB point, a drain and a source of the fifth transistor are respectively connected to the first node and the Q point, a gate of the sixth transistor is connected to the QB point, a source and a drain of the sixth transistor are respectively connected to the first node and a low electrical potential terminal, and two terminals of the first capacitor are respectively connected to the Q point and the second node.

19. The display device as claimed in claim 18, wherein the primary pull-up unit comprises a seventh transistor and a second capacitor;
a gate of the seventh transistor is connected to the second node, a drain and a source of the seventh transistor are respectively connected to a driving electrical potential terminal and the primary output terminal, and two terminals of the second capacitor are respectively connected to the second node and the primary output terminal.

20. The display device as claimed in claim 19, wherein the primary pull-down driving unit comprises an eighth transistor and a ninth transistor;
a gate of the eighth transistor receives the control signal, a source and a drain of the eighth transistor are respectively connected to the high electrical potential terminal and the QB point, a gate of the ninth transistor is connected to the Q point, and a source and a drain of the ninth transistor are respectively connected to the QB point and the low electrical potential terminal.
